(19) United States
(12) Patent Application Publication
(10) Pub. No.: US 2024/0387142 A1
(43) Pub. Date: Nov. 21, 2024

(54) INTEGRATED SYNCHRONOUS SYSTEM FOR GRIDDED ION SOURCES

(71) Applicant: VEECO INSTRUMENTS INC., Plainview, NY (US)

(72) Inventors: Mohammad SAGHAYEZHIAN, Plainview, NY (US); Binyamin RUBIN, Plainview, NY (US); Kirill GUTSOL, Plainview, NY (US)

(21) Appl. No.: 18/661,315

(22) Filed: May 10, 2024

Related U.S. Application Data
(60) Provisional application No. 63/503,109, filed on May 18, 2023.

(51) Int. Cl. H01J 37/304; H01J 37/08

(52) U.S. Cl. CPC H01J 37/304; H01J 37/08

(57) ABSTRACT

An ion beam system including an integrated power control system between the power supplies and the grids. The power control system includes a fast, high-power solid state switch such as an insulated gate bipolar transistor (IGBT). The power control system may include a resistor array, e.g., to dissipate current surge. The integrated power control system provides synchronous operation of the grid power supplies.

### CROSS REFERENCE

This application claims priority to U.S. provisional application Ser. No. 63/503,109 filed May 18, 2023, the entire disclosure of which is incorporated herein by reference for all purposes.

### BACKGROUND

In ion beam deposition applications, the rate of material sputtering is directly related to the extracted ion beam power from an ion source. The extracted power is defined based on the ion current and beam voltage, which is governed by space-charge limitations. To control deposited material thickness, precise control is needed that enables instantaneous switching of ion beam on and off. In high power ion beam applications where maximum beam current and voltage (based on space-charge) is needed and a small module footprint is desired, the system is more prone to plasma instabilities and arcing, which can impact the reliability and repeatability of the ion source operation.

What is desired is fast, accurate and reliable control of the ion source and plasma.

### SUMMARY

The present disclosure describes a control system that provides accurate, synchronized and fast control of ion source functions such as ion beam ignition, ion beam extraction, plasma ignition, ion beam extraction, ion beam switching, plasma recovery, arc suppression, RF generator control, diagnostics and grid conditioning. The present disclosure also describes a control system that provides ion source and system diagnostics, as well as monitoring of system maintenance needs (e.g., grid conditioning or tracking ion impingement).

The present disclosure is directed to an integrated synchronous system (ISS)—a control system for high or low power ion beam deposition (IBD) and ion beam etch (IBE) systems; it is applicable to systems having any type and/or number of accelerator grids. The ISS includes a component that is positioned between and separates the load from the grid power supplies. The power supplies can be integrated into the ISS or configured outside of the ISS. The ISS utilizes a series of high-power insulated gate bipolar transistors (IGBTs) as well as fast sensing electronics, that with a defined algorithm, enable the ISS to activate, deactivate or perform the aforementioned functions. The electronics can be customed to a particular (IBE/IBD) system and can be upgradable, as desired.

The ISS provides fast separation and connection of the plasma load to and from the grid power supplies, using a highly customizable firmware algorithm, which enables the ISS to eliminate delays stemming from communications, response time of an individual power supply, and rise and fall time of the voltage on the power supply output. Because of this, the ion source operates with more stability, resulting in improved wafer yield of the system, both in terms of reducing scrap and increasing throughput.

Because the ISS separates the load from the grid power supplies, the transition from one extraction power to another, low to high or vice versa, can be essentially instant, eliminating the need for physical shutter, which is commonly used for low defect/particle/contamination operations in deposition/etch systems.

The ISS can perform any or all of ion beam ignition control, electronic shutter control (including plasma ignition, ion beam extraction, ion beam switching), plasma recovery, arc suppression, system diagnostics, and grid conditioning monitoring.

Thus, this disclosure describes plasma ignition as one of the functions of the ISS, ion beam switching as one of the functions of the ISS, ion beam extraction as one of the functions of the ISS, plasma recovery as one of the functions of the ISS, arc detection and handling as one of the functions of the ISS, and maintenance monitoring, such as grid conditioning, filtering RF noise, and protecting power supplies.

Another function of the ISS is diagnostics, such as automatic perveance tracking and locating failure points, as one of the functions of the ISS. The diagnostic function of the ISS enables fast automatic perveance measurements to maintain the source-grid in perveance, track grid life, and locate failure point during a plasma loss event. This feature provides process consistency, reliability, and stability.

Although the ISS control system is particularly suitable for ion systems or sources that operate at high power density, producing a high sputtering rate, the ISS can be used on any ion source system with any magnitude of extracted power.

This Summary is provided to introduce a selection of concepts in a simplified form that are further described below in the Detailed Description. This Summary is not intended to identify key or essential features of the claimed subject matter, nor is it intended to be used to limit the scope of the claimed subject matter. These and various other features and advantages will be apparent from a reading of the following Detailed Description.

### BRIEF DESCRIPTION OF THE DRAWING

FIG. 1 is a schematic side view of a portion of a generic ion beam deposition system.

FIG. 2 is a schematic block diagram of an ISS control system for an ion beam system.

FIG. 3 is a schematic block diagram of another ISS control system for an ion beam system.

FIG. 4 is a graphical representation of performance for an ion beam system with inherent asynchrony in grid power supply control.

FIG. 5 is a graphical representation of performance for an ion beam system controlled by an ISS control system in which the power supplies are synchronized.

### DETAILED DESCRIPTION

This disclosure is directed to an integrated synchronous system (ISS) for high power gridded ion beam deposition/etch systems. The systems operate at ion beam power of at least 200 W, in some embodiments at least 1000 W, in other embodiments at least 2000 W, and even as high as 4000 W and higher. The ISS control system can be applied to ion sources with one or more accelerator grids. Most industrial ion sources utilize three grids, which in the order of plasma direction upstream to downstream, are called screen/accelerator/decelerator grids or screen/acceleration/deceleration grids or beam/suppressor/ground grids; the latter nomenclature is adopted for the remainder of this disclosure.

In general, gridded ion sources with large grid surface areas have transient instabilities during ignition and during change in operating conditions; this is especially true for ion sources operating at high beam current, power, and voltage. These instabilities can result in extinguishing of the plasma and other process interruptions. The underlying reasons for these instabilities are partially related to asynchronous operation, dissimilar rise- and fall-time characteristics of voltage provided by the beam grid and the suppressor grid power supplies, and the interaction of the grids with electrical line capacitance of high-voltage power circuits, which can lead to coupling of neutralizers with the ion source and quick current saturation of the beam grid and suppressor grid power supplies upon energizing the grids.

By having the ISS positioned between the grid power supplies and the load, the power supplies are protected from open or shorting faults. Additionally, any delayed response is reduced and, in some cases, eliminated; in some cases, the grid voltages are applied synchronously (simultaneously). Having the grid voltages applied synchronously is important as in case of asynchrony in power supplies rise times (onset, characteristics, or communication), the gridded system will go through a transitory state, such that at some point in initializing the operation, only one grid is at the requested electric potential, or the power delivered to grids at each time instant is not in accordance with space-charge limitation. In both cases, out of perveance beam extraction can occur. This causes damage to grids, increases ion/electron impingement (leading to structural grid damage), and can saturate/damage the power supplies, lowering the operation stability and lifetime of the ion source as a whole, potentially generating particles or impurities. In addition, the increased impingement can lead to contamination of the process with grid materials, especially in reactive etch applications.

Another advantage of the ISS configuration having the load/power supply separation is the seamless transition from beam parameters with various power levels, in accordance with space-charge limitations.

As indicated above, the ISS can perform, among others, seven main functions including plasma ignition, space-charge (perveance) controlled beam extraction, ion beam switching, arc detection/suppression, plasma recovery, system diagnostics, and in-situ maintenance (e.g., grid conditioning).

For beam ignition, the suppressor grid is disconnected from the suppressor power supply and electrically connected to the beam grid, which in the presence of an active neutralizer and sufficient gas and rf-power, the plasma is ignited. After a defined delay (microsecond to second time scale), the suppressor grid is disconnected from the beam grid and appropriately connected to suppressor power supply. The time interval of each step of this function is adjustable. The ISS can confirm ignition in either of the two manners: detecting an extraction current rise or an impedance change from RF matching network. In principle, there is no need for extraction after ignition, which means that the source ignites without any ion extraction; this is an advantage as previously extraction was needed to validate the plasma ignition and ion current set point. By having the ISS control system perform an ultra-fast and regulated electronic shutter, there is no need for a physical shutter.

Ultra-fast sensing of the beam, suppressor, and ground grid currents and voltages, along with controlling the RF generator by the ISS, enables fast perveance data collection to always maintain the source/grid within bounds of the space-charge limit (as defined by Child-Langmuir law). Therefore, as the life of a grid progresses, the perveance is kept constant. This is also an active way of assessing grid life and an indicator for preventive maintenance cycles.

Power control during plasma ignition, ion beam extraction, and ion beam switching are other features of the ISS. As opposed to the current state of the art (e.g., U.S. Pat. No. 6,225,747 B1) where during plasma ignition, ion beam extraction, and ion beam switching the power supply is de-energized, with the ISS the beam, suppressor, and ground power supplies are always energized at the set point voltages. The ISS connects/disconnects the plasma to/from the power supplies; therefore, the asynchrony between the power supplies is removed and the extraction occurs, e.g., faster than 100 microseconds. This feature improves process controls; e.g., the thin film deposition thickness control becomes more accurate. Also, with the ISS, there is no ramp time for the set point current, as the plasma remains in the same status before and after any of all of plasma ignition, ion beam extraction, and ion beam switching.

After any plasma ignition, ion beam extraction, and ion beam switching, during deposition or etching, the ISS control system continuously monitors the grid current and/or voltage, e.g., for an arc occurrence mid-process. If an arc is detected, an arc suppression algorithm in the ISS is activated.

This arc detection and suppression is another feature of the ISS. Fast and high current electrical discharges (arcs) are detrimental to ion source stability, grid life and the overall process. The response to a detected arc differs depending on the duration of the arc, the current magnitude and the location of the arc. Arcs (usually short-lived current surges, when current magnitude exceeds the expected by a factor of ten or more) are divided into three main categories:
A. Arcs between beam grid and suppressor grid;
B. Arcs between suppressor grid and ground grid; and
C. Arcs or internal discharges in upstream plasma within the plasma vessel or gas feed.
   By simultaneously and continuously monitoring beam grid, suppressor grid, and ground grid voltage and current, proper actions are performed by the ISS in an arc or discharge incidence, which are as follows:
A. Type A arc: IF the beam voltage drops below a defined value AND the beam and suppressor currents exceed a defined value, THEN an arc between the beam grid and the suppressor grid has occurred.
   Response: disconnect grids from power supplies, connect them together and to ground. After a defined time delay, disconnect the beam grid and the suppressor grid from each other and from ground and connect the grids to their appropriate power supplies. Wait for the next command.
B. Type B arc: IF the suppressor voltage drops below a defined value, AND the suppressor current and ground current exceeds a defined value, THEN an arc between the suppressor grid and the ground grid has occurred.
   Response: disconnect the beam, suppressor, and ground grids from their power supplies, connect all grids together and to ground. After a defined time delay, disconnect all grids from each other and connect the grids to their appropriate power supplies. Wait for the next command.
C. Type C arc or internal discharge: IF the beam voltage drops below a defined value AND the beam current exceeds a defined value, while suppressor grid and ground grid voltages and currents are steady, THEN an upstream plasma discharge has occurred.
   Response: Check RF generator and matching network to confirm presence of plasma.
      i. IF plasma is extinguished, THEN run ignition sequence OR wait for the next command.
      ii. IF plasma is present, GoTo electronic shutter, wait for the next command.
         Using the voltage and current sensing facilities, the ISS can identify the fault location in the source and, based on input from a user, perform the proper response. The response could be pre-defined or interactive.

Plasma recovery is another function of the ISS. Plasma instabilities might occur due to transient parasitic plasma creation, ground current streamers around the plasma vessel, transient coupling of the neutralizer to the plasma vessel at high pressure, downstream plasma creation, etc., all of which can lead to loss of plasma. By monitoring forward and reflected RF power and beam current, the ISS detects plasma loss and can immediately ignite plasma with the electronic shutter closed.

Conditioning the ground grid can be done to extend the working life of the grid, particularly for high power etch or deposition processes. The conditioning process is an in-situ cleansing of grids of the ion beam system that includes applying a negative bias on the downstream-most grid. In plasma ion beam applications, back sputtered materials are deposited and accumulated on the down-stream surface of the grids. Additionally, it is not uncommon for sputtered material to delaminate in the form of flakes and redeposit. Overtime, this leads to pre-mature failure of grids due to grid arcing or defect generation. Dependent on the frequency or intensity of Type B arcing incidences, or at set time intervals, the ISS executes a pre-defined ground grid conditioning.

The ISS can detect potential delamination and backsputtering by analyzing the ground and suppressor currents. If a potential arc source is detected, the ISS can activate electronic shutter (closed), disconnect the ground grid from ground, connect the ground grid to a power supply, then apply a pulsed (with controlled duty cycle) high voltage to the ground grid to “burn off” or remove the potential arc source. After each high voltage pulse, the resistance between the suppressor and ground grids is measured, confirming the removal of the arc source. Additional details regarding cleaning ground grids can be found in co-pending U.S. application Ser. No. 18/504,438 titled GRID SURFACE CONDITIONING FOR ION BEAM SYSTEM, the entire disclosure of which is incorporated herein by reference.

In the following description, reference is made to the accompanying drawing that forms a part hereof and in which is shown by way of illustration at least one specific implementation. The following description provides additional specific implementations. It is to be understood that other implementations are contemplated and may be made without departing from the scope or spirit of the present disclosure. The following detailed description, therefore, is not to be taken in a limiting sense. While the present disclosure is not so limited, an appreciation of various aspects of the disclosure will be gained through a discussion of the examples provided below. In some instances, a reference numeral may have an associated sub-label consisting of a lower-case letter to denote one of multiple similar components. When reference is made to a reference numeral without specification of a sub-label, the reference is intended to refer to all such multiple similar components.

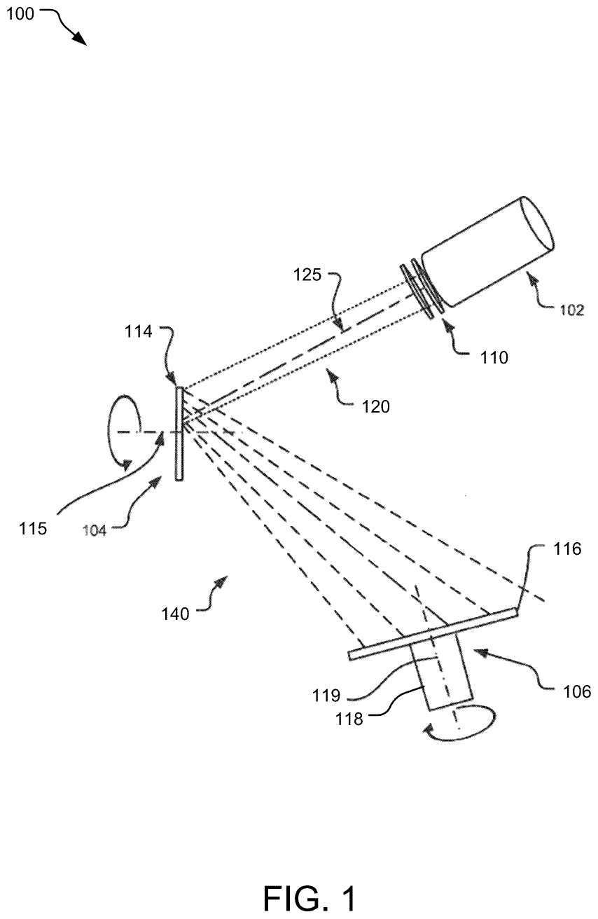

FIG. 1 illustrates a generic diagram of an ion beam system 100. Even though the implementation of the ion beam system 100 is shown as an ion beam sputter deposition system, components of the ion beam system 100 may also be used with some alteration for implementing any or all of an ion beam etch system, an ion implantation system, an ion beam deposition system, an ion beam assisted deposition system, etc. The system 100 can be used to, e.g., deposit, deposit and modify, and/or deposit and etch material.

The ion beam system 100 includes an ion beam source 102, a target assembly 104, and a substrate assembly 106 for supporting a substrate 116. Note that the substrate assembly 106 may include a single large substrate 116 or a sub-assembly holder that holds multiple smaller individual substrates 116. The substrate 116 may be formed of, for example, one or more layers of silicide(s), nitride(s), oxide(s), metal(s) including alloys, or ceramic(s).

The ion beam source 102 generates an ion beam 120, which can include a plurality of ion beamlets targeted or directed toward the target assembly 104, which includes at least one target 114 affixed to the target assembly 104 that includes a material desired to be deposited on the substrate 116. The ion beam 120 has a centerline axis 125 that is targeted or directed toward the target assembly 104 such that the ion beam 120 completely or near completely impinges on the target assembly 104. The target assembly 104 is located on a platform that, if needed, can rotate the target assembly 104 about a given axis 115. In some designs, the target assembly 104 may tilt. The ion beam 120, upon striking the target assembly 104, generates a sputter plume 140 of material from the target 114.

Examples of material for the target 114 include, without limitation, metals such as titanium (Ti), tungsten (W), molybdenum (Mo), tantalum (Ta), ruthenium (Ru), cobalt (Co), copper (Cu), and rhodium (Rh), dielectric and semiconductor materials such as, but not limited to, nitrides of metals and semiconductors such as titanium nitride (TiN), tantalum nitride, (TaN) silicon nitride (Si₃N₄), molybdenum nitride (MoN), tungsten nitride (WN, W₂N, WN₂), oxides of metals and semiconductors such as silicon oxide (SiO₂), titanium oxide (TiO), aluminum oxide (Al₂O₃), silicides of metals and semiconductors such as tungsten silicide (W₅Si₃), molybdenum silicide (MoSi₂), titanium silicide (Ti₅Si₃), and other types of metal, dielectric, and semiconductor targets.

The ion beam 120 strikes the target 114 at such an angle so that the sputter plume 140 generated from the target 114 travels towards the substrate assembly 106 and the substrate 116. In some configurations of the ion beam system 100, the sputter plume 140 is divergent as it travels from the target 114 towards the substrate assembly 106 and may partially overspray the substrate 116. However, in other configurations, the sputter plume 140 may be made more or less concentrated so that its resulting deposition of material is more effectively distributed over a particular area of the substrate 116.

The substrate assembly 106 is located such that the sputter plume 140 strikes the substrate 116 at a desired angle as well. In one example configuration of the ion beam system 100, the substrate assembly 106 is attached to a fixture 118 that allows the substrate assembly 106 to be moved in a desired manner, including rotation of substrate assembly 106 about its axis 119 or pivoting the fixture 118 to tilt the substrate assembly 106 to alter its angle with respect to the sputter plume 140.

In one example of the ion beam system 100, the ion source 102 generates ions that are positively charged. However, in an alternate example, the ion source 102 generates ions that are negatively charged. The subsequent disclosure herein assumes that the ions generated by the ion source 102 are positively charged. The ion source 102 may be a DC type, a radio frequency (RF) type or a microwave type gridded ion source.

The system 100 may include one or more grids 110 proximate the ion beam source 102 for directing the ion beam 120 from the ion beam source 102 to the target assembly 104. In one configuration of the ion beam system 100, the grids 110 steer the ion beamlets such that the ion beam 120 is divergent from the centerline axis 125 of the ion source 102, compared to if no bulk ion beam steering was provided. In an alternate configuration, the grids 110 steer the ion beamlets such that the ion beam 120 is not divergent from the centerline axis 125. Other constructions and configurations may also be provided. The grids 110 can cause the ion beam 120 to have a symmetric or asymmetric cross-sectional profile around a beam axis.

The grids 110 have holes or apertures therethrough to allow the beamlets of the ion beam 120 to pass through the grids 110. The individual holes in the grids 110 may be positioned to yield the highest density of holes per area to maximize ions extracted from the ion source 102. The grids 110 may have a rectilinearly or elliptically shaped pattern of holes. The hole pattern can be, e.g., circular, elliptical, symmetrical or asymmetrical.

The grids 110 can be, for example, planar with a circular or rectangular shape, arranged parallel to each other, with each grid having a substantially similar dimension; in other examples, the grids 110 can be curved, e.g., with a spherical or cylindrical shape.

The grids 110 are positioned such that the beam grid forms the downstream boundary of a discharge chamber of the ion beam source 102. Plasma is generated inside the discharge chamber (e.g., from a noble gas, such as argon, or a reactive gas such as oxygen), and the grids 110 extract and accelerate ions from the plasma through the grid holes toward the target 114. The ions from the source 102 are organized in an ion beam made up of individual beamlets, where a beamlet is made of ions accelerating through individual sets of corresponding holes in the grids 110.

In practice, when three grids 110 are present (e.g., beam/suppressor/ground grids), individual ions of each beamlet flood generally along a center axis through a hole in the beam grid in a distribution across the open area of the hole. The beamlet ions continue to accelerate toward the suppressor grid, propagating generally along a center axis through a corresponding hole of the suppressor grid. Thereafter, the momentum imparted by the electric field between the beam grid and the suppressor grid on the beamlet ions accelerates them generally along a center axis through a hole in any ground grid in a distribution across the open area of the hole and toward the downstream positioned target 114.

As indicated above, the system 100 shown is a generic and generalized system. The system 100 may include any additional features, such as a reactive gas source, an assist ion source, an assist gas source, various heaters, neutralizers, turrets for multiple rotational targets, and diagnostic probes and sensors.

The system 100 may operate at any conventional operating parameters under any operating conditions. For example, the system 100 may be under inert atmosphere, may have a reactive gas added and/or a noble gas. For example, introduction of gases may be as low as 1 sccm to as high as 100 sccm. The system 100 typically operates at a process (chamber) pressure of less than 10⁻³ torr, e.g., 1χ10⁻⁵ to 1×10⁻³ torr. The system 100, particularly the ion source 102, can utilize a high energy ion beam, e.g., having a voltage ranging from 40 V to 2000 V, e.g., having a wattage of at least 1200 W, e.g., at least 1500 W, e.g., at least 2000 W, and e.g., 3000 W, and higher. The system can provide a net deposition rate greater than 10 angstroms/minute (Å/min), often greater than 50 Å/min, and sometimes greater than 200 Å/min.

Each of the grids 110 is operably connected to a power supply or source to independently apply power/current/voltage to each of the grids 110. The ground grid can be grounded with no power supply connected to it.

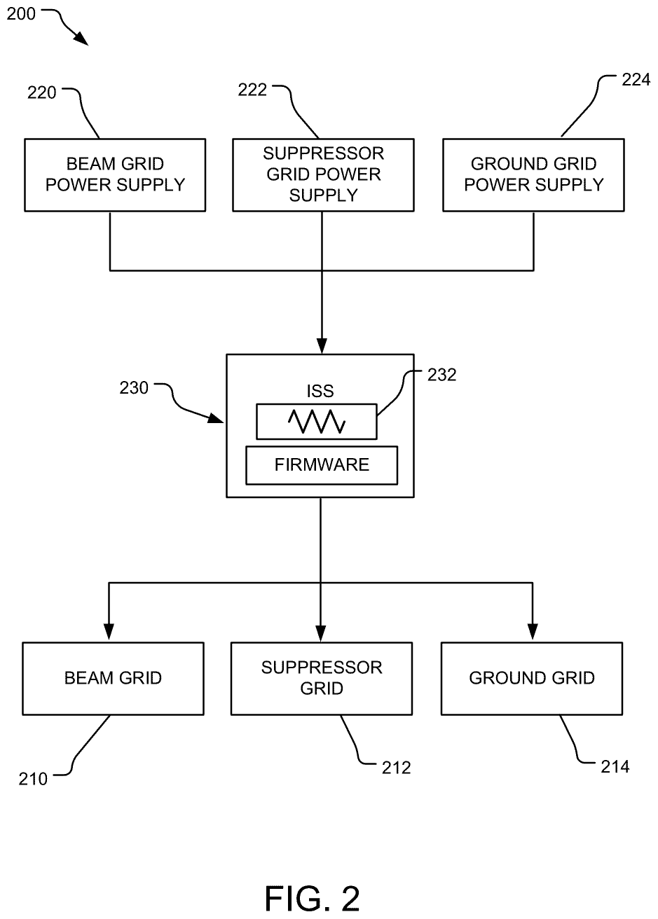

FIG. 2 illustrates, schematically, the operable location of an ISS control system in relation to the grid power sources and the grids of an example ion beam system (e.g., grids 110 of FIG. 1).

FIG. 2 shows a system 200 with a beam grid 210, suppressor grid 212 and ground grid 214. Each of the grids 210, 212, 214 has its own power supply, shown as beam grid power supply 220, suppressor grid power supply 222, and ground grid power supply 224. The ground grid 214 includes the power supply 224 for an in-situ cleansing or grid conditioning, which is done by applying a negative bias to the ground grid 214; it is understood that not all systems will have a power supply for the ground grid.

Present in the system 200, operably positioned between the grids 210, 212, 214 and the power supplies 220, 222, 224 is an ISS control system 230. This particular ISS system 230 includes a resistor array 232.

Rather than the power from the power supplies 220, 222, 224 going directly into the respective grids 210, 212, 214, with each power supply 220, 222, 224 being controlled by its own controller, the cables from the power supplies 220, 222, 224 are connected to and managed by the ISS control system 230. Rather than each power supply being individually controlled, the ISS control system 230 activates the power supplies 220, 222, 224 cooperatively, providing power to the grids 210, 212, 214 as determined by the algorithm in the control system 230.

The ISS power control system 230 includes at least one fast, high-power solid-state switch, such as an insulated gate bipolar transistor (IGBT) switch. Other solid-state switches may be used, such as simple solid-state transistors, such as a bipolar junction transistor (BJT), MOSFETs, and thyristors.

The resistor array 232 in the ISS control system 230 dissipates the current surge and protects the power supplies 220, 222, 224, e.g., when the power is initiated. The ISS control system 230 diverts this current surge to the resistor array 232 for a very short period of time (e.g., about 100 microseconds). After surge dissipation, the ISS control system 230 removes the resistor array 232 from the circuit and connects the load directly to the power supplies 220, 222, 224.

The resistor array includes at least one resistor, typically multiple resistors in parallel. The resistor(s) are a high-power resistor, capable of withstanding high-power surges (e.g., at least 1000 W, at least at least 1200 W, in some embodiments at least 1500 W, in other embodiments at least 2000 W, and even as high as 3000 W). The resistor(s) may be, e.g., a wire-wound resistor or a semiconductor resistor.

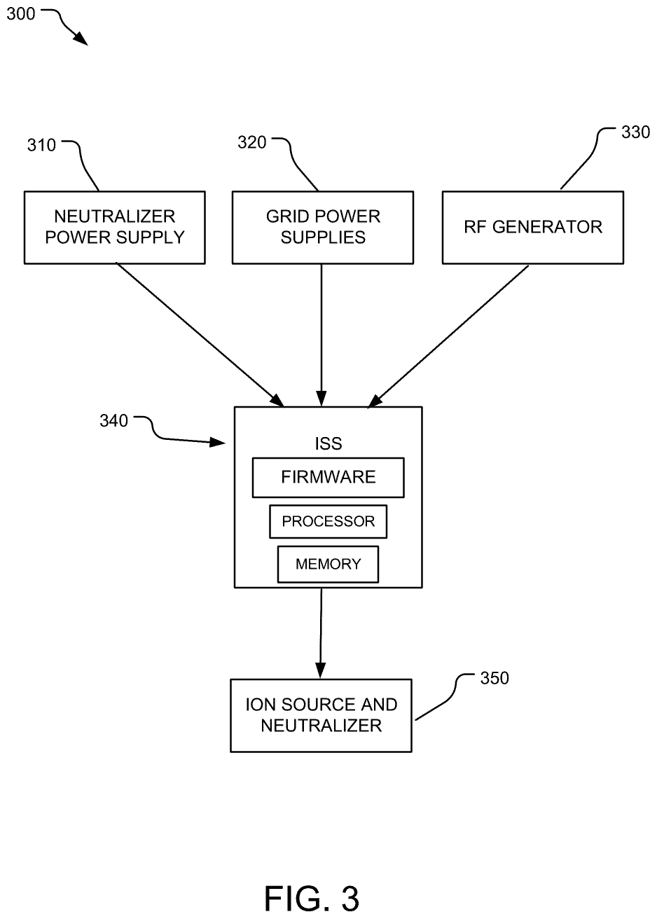

FIG. 3 illustrates, schematically, another example of an operable location of an ISS control system. FIG. 3 shows the relation between neutralizer, grid and RF power supplies with respect to the ISS control system and how the ISS control system is related to the ion source and neutralizer.

FIG. 3 shows a system 300 with a neutralizer power supply 310 and power supplies 320 for the grids of the ion beam system, such as a beam grid power supply, a suppressor grid power supply, and optionally a ground grid power supply. The system 300 includes an RF generator 330 for the ion beam source (e.g., the ion beam source 102 of FIG. 1). Power from the supplies 310, 320 energizes the respective ion sources and the neutralizer 350.

Operably positioned between the power supplies/generator 310, 320, 330 is an ISS control system 340. The ISS control system 340 includes at least one fast, high-power solid-state switch, such as an insulated gate bipolar transistor (IGBT) switch. Other solid-state switches may be used, such as simple solid-state transistors, such as a bipolar junction transistor (BJT), MOSFETs, and thyristors. The control system 340 may include at least one resistor.

The ISS control system 340 dissipates the current surge and protects the power supplies 310, 320, 330, e.g., when the power is initiated. After surge dissipation, the ISS control system 340 removes the solid-state switch from the circuit and connects the ion sources and the neutralizer 350 directly to the power supplies 310, 320, 330.

Similar to the system 200 described above, rather than each power supply 310, 320, 330 being controlled by its own controller, the cables from the power supplies 310, 320, 330 are connected to and managed by the ISS control system 340. The ISS control system 340 activates the power supplies 310, 320, 330 cooperatively, providing power to the ion sources and the neutralizer 350 as determined by the algorithm in the ISS control system 340. The power supplies can be integrated as part of the ISS control system or can operate externally, as independent unit(s), with respect to the ISS control system.

The ISS control system, such as control systems 230, 340, and variations thereof, is based on firmware, rather than conventional software. The firmware includes instructions saved or written in a non-volatile memory (such as read-only-memory (ROM) or programmable memory such as EPROM, EEPROM, or flash) in a circuit board or other circuitry that is executed, e.g., by a processor. Firmware provides a low-level control, compared to systems having an operating system with upgradeable software. Having an onboard control algorithm (firmware), allows faster decision making (e.g., 1 microsecond) based on data collected by the ISS control system.

The firmware in the ISS control system minimizes and preferably eliminates delays stemming from communications, response time of an individual power supply, and rise and fall time of the voltage on the power supply output; this is beneficial for precise control in a system (e.g., an ion source), as the response time can be on the order of a microsecond or less. Because of this, the power supplies, and as a result, the overall process, operate with more precision, stability and repeatability. Because the ISS control system separates the load from the grid power supplies, the transition from one extraction power to another, low to high or vice versa, can be essentially instant. The ISS control system can be used to control any or all of ion beam ignition control, electronic shutter control including plasma ignition, ion beam extraction, and ion beam switching, plasma recovery, arc suppression, system diagnostics, and grid conditioning monitoring.

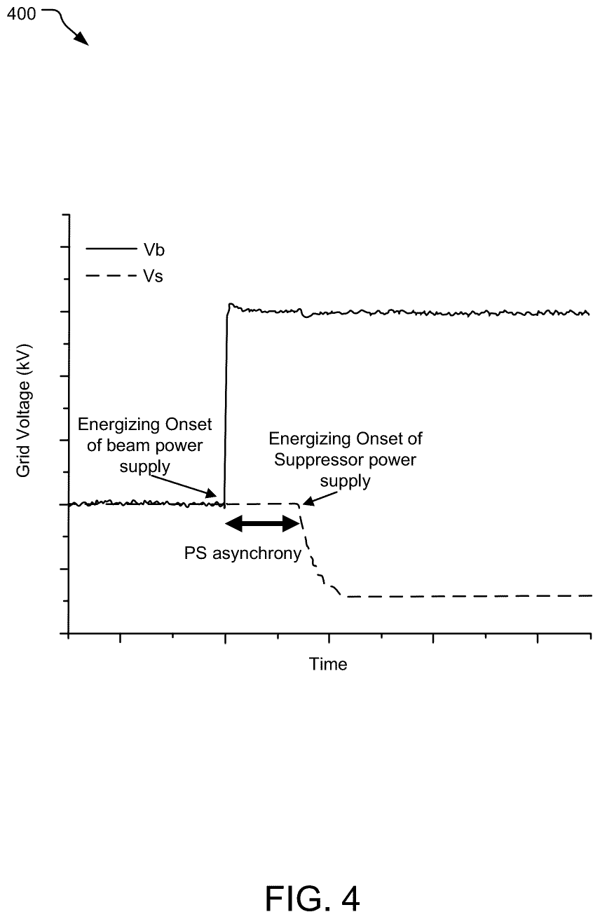

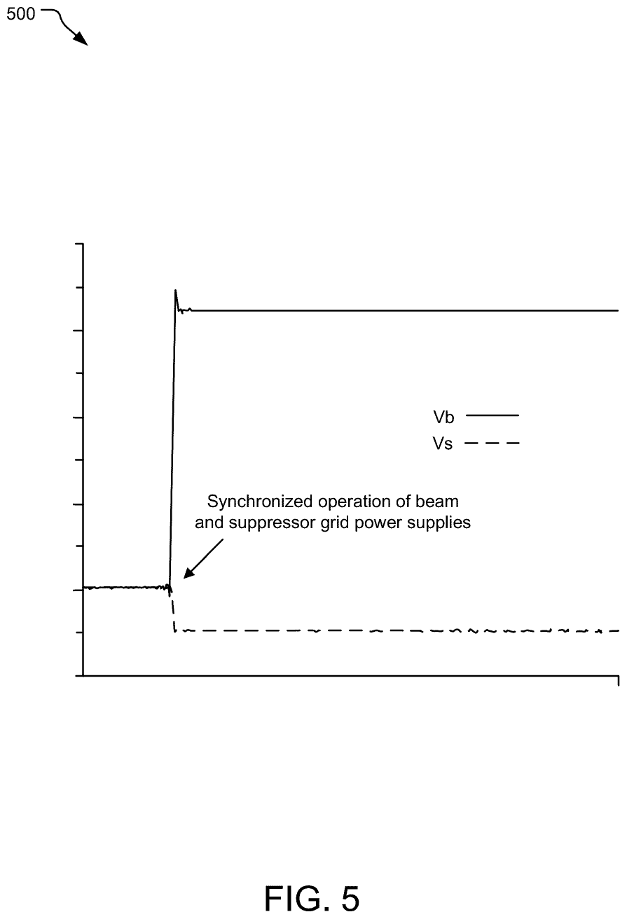

FIGS. 4 and 5 are graphical representations of performance for various ion beam systems with and without an ISS power control system according to this disclosure, and with and without a resistor array. The graphs show the benefits of incorporating a power control system between the power sources and the grids.

FIG. 4 shows, via graph 400, the performance of an ion beam system lacking any power control system as described herein. Rather, the ion beam system has each power source directly electrically connected to its respective grid. The graph 400 shows the voltage of the beam grid (Vb) and the voltage of the suppressor grid (Vs) after disengaging the relay after plasma ignition. The delay between the rise time in beam voltage (Vb) and suppressor voltage (Vs) is apparent; this is referred to as “railing.”

FIG. 5 shows the highly synchronized onset and immediate rise of beam and suppressor power supplies, using an ISS control system. FIG. 5 shows, via graph 500, the performance of an ion beam system having an ISS control system. The graph 500 shows the voltage of the beam grid (Vb) and the voltage of the suppressor grid (Vs) after disengaging the relay after plasma ignition. No delay is apparent between the increase in beam voltage (Vb) and the decrease in suppressor voltage (Vs).

In addition to the synchronized operation of the grid power supplies as seen in FIG. 4, by having an ISS control system in the ion beam system, the following has been found:
Since power supplies are synchronized, process step transients are reduced by more than two orders of magnitudes;
the ion beam stays in perveance and optimal divergence, therefore, contamination arising from target overspray is minimized;
grid lifetime is increased since initial grid impingement is eliminated; and
the transitory voltage drop on the suppressor power supply is eliminated, therefore, no electron back streaming occurs.

The above specification and examples provide a complete description of the process and use of exemplary implementations of the invention. The above description provides specific implementations. It is to be understood that other implementations are contemplated and may be made without departing from the scope or spirit of the present disclosure. The above detailed description, therefore, is not to be taken in a limiting sense. Features and elements from one implementation or embodiment may be readily applied to a different implementation or embodiment. While the present disclosure is not so limited, an appreciation of various aspects of the disclosure will be gained through a discussion of the examples provided.

Unless otherwise indicated, all numbers expressing feature sizes, amounts, and physical properties are to be understood as being modified by the term “about.” Accordingly, unless indicated to the contrary, the numerical parameters set forth are approximations that can vary depending upon the desired properties sought to be obtained by those skilled in the art utilizing the teachings disclosed herein.

As used herein, the singular forms “a”, “an”, and “the” encompass implementations having plural referents, unless the content clearly dictates otherwise. As used in this specification and the appended claims, the term “or” is generally employed in its sense including “and/or” unless the content clearly dictates otherwise.

Spatially related terms, including but not limited to, “lower”, “upper”, “beneath”, “below”, “above”, “on top”, etc., if used herein, are utilized for ease of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

Since many implementations of the invention can be made without departing from the spirit and scope of the invention, the invention resides in the claims hereinafter appended. Furthermore, structural features of the different implementations may be combined in yet another implementation without departing from the recited claims.

What is claimed:

1. An ion beam system comprising:
at least one power supply;
at least one power load; and
an integrated power control system comprising a fast, high-power solid state switch electrically connected between the at least one power supply and the at least one power load, the solid state switch controlled by firmware configured to minimize response time and a rise and fall time of a voltage of the at least one power supply.

2. The ion beam system of claim 1, wherein the fast, high-power solid state switch is an insulated gate bipolar transistor (IGBT).

3. The ion beam system of claim 1, wherein the fast, high-power solid state switch is a solid-state transistor.

4. The ion beam system of claim 3, wherein the solid-state transistor is a bipolar junction transistor (BJT), MOSFET, or thyristor.

5. The ion beam system of claim 1, wherein:
the at least one power supply comprises one or more of a neutralizer power supply, an RF power supply, a beam grid power supply, a suppressor grid power supply, and a ground grid power supply; and
the at least one power load comprises one or more of a neutralizer, an RF generator, a beam grid, a suppressor grid, and a ground grid.

6. An ion beam system comprising:
a neutralizer with a neutralizer power supply;
an RF generator with an RF power supply;
a beam grid power supply and a suppressor grid power supply;
a beam grid downstream of the beam grid power supply and a suppressor grid downstream of the suppressor grid power supply; and
an integrated power control system comprising a fast, high-power solid state switch operably connected between the power supplies and the grids, the solid state switch controlled by firmware configured to minimize response time and a rise and fall time of a voltage of the at least one power supply.

7. The ion beam system of claim 6 further comprising a ground grid and a ground grid power supply, with the integrated power control system operably connected between the ground power supply and the ground grid.

8. The ion beam system of claim 6, wherein the fast, high-power solid state switch is an insulated gate bipolar transistor (IGBT).

9. The ion beam system of claim 6, wherein the fast, high-power solid state switch is a solid-state transistor.

10. The ion beam system of claim 9, wherein the solid-state transistor is a bipolar junction transistor (BJT), MOSFET, or thyristor.

11. An ion beam system comprising:
a plurality of grids and a power supply for each grid; and
an integrated power control system operably connected between the power supplies and the grids, the power control system comprising firmware configured to minimize response time and a rise and fall time of a voltage of the power supplies, the power control system configured to perform at least one of:
ion beam ignition,
space-charge (perveance) controlled beam extraction,
electronic shuttering,
arc detection and suppression,
plasma recovery,
system diagnostics, and
grid conditioning.

12. The ion beam system of claim 11, wherein the power control system is configured to perform all of:
ion beam ignition,
space-charge (perveance) controlled beam extraction,
electronic shuttering,
arc detection and suppression,
plasma recovery,
system diagnostics, and
grid conditioning.

13. A method comprising:
detecting a current arc in an ion beam system, comprising:
monitoring voltage and current of a beam grid, a suppressor grid, and a ground grid of an ion beam system,
detecting an arc between the beam grid and the suppressor grid responsive to a predetermined drop in voltage of the beam grid and a predetermined increase in current of the beam grid and the suppressor grid;
detecting an arc between the suppressor grid and the ground grid responsive to a predetermined drop in voltage of the suppressor grid and a predetermined increase in current of the suppressor grid and the ground grid.

14. The method of claim 13 further comprising:
responsive to detecting an arc between the beam grid and the suppressor grid, disconnecting the beam grid and the suppressor grid from their power supplies, connecting the beam grid and the suppressor grid together and to ground.

15. The method of claim 14 further comprising:
after a defined time delay, disconnecting the beam grid and the suppressor grid from each other and from ground, and connecting the beam grid and the suppressor grid to their appropriate power supply.

16. The method of claim 13 further comprising:
responsive to detecting an arc between the suppressor grid and the ground grid, disconnecting the beam grid, the suppressor grid, and the ground grid from their power supplies, and connecting the beam grid, the suppressor grid, and the ground grid together and to ground.

17. The method of claim 16 further comprising:
after a defined time delay, disconnecting the beam grid, the suppressor grid, and the ground grid from each other and connecting the beam grid, the suppressor grid, and the ground grid to their appropriate power supply.
